(19) United States
(12) Patent Application Publication
(10) Pub. No.: US 2025/0293195 A1
(43) Pub. Date: Sep. 18, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Yoshiko TAKAHASHI, Yokohama Kanagawa (JP)

(21) Appl. No.: 18/824,793

(22) Filed: Sep. 4, 2024

(30) Foreign Application Priority Data
Mar. 14, 2024 (JP) 2024-040280

(51) Int. Cl. H01L 23/00; H01L 23/31; H01L 23/495

(52) U.S. Cl. CPC H01L 24/45; H01L 23/49586; H01L 24/48; H01L 23/3107; H01L 24/32; H01L 24/73; H01L 2224/32245; H01L 2224/45147; H01L 2224/45572; H01L 2224/45647; H01L 2224/48245; H01L 2224/73265

(57) ABSTRACT

According to one embodiment, a semiconductor device has a semiconductor chip. It has a terminal which is connected to the semiconductor chip and which comprises a first surface region containing copper. It has a functional film formed on at least a portion of a surface of the first surface region. It has a resin which covers a portion of the terminal and the semiconductor chip. The functional film comprises an organic film containing oxygen atoms. The organic film is bonded to the resin.

### CROSS-REFERENCE TO RELATED APPLICATION

This application is based upon and claims the benefit of priority from Japanese Patent Application No. 2024-040280, filed Mar. 14, 2024, the entire contents of which is incorporated herein by reference.

### FIELD

Embodiments described herein relate generally to a semiconductor device.

### BACKGROUND

A semiconductor device in which contact between a terminal and the outside air is curbed by sealing the terminal having a lead frame, a wire, and the like with a molding resin has been proposed. However, for example, when the terminal is constituted using a metal material such as copper, it is difficult to enhance adhesion between the terminal and the molding resin, and there is concern that the molding resin may peel off from the terminal. If the molding resin peels off from the terminal and the terminal comes into contact with the outside air, the terminal deteriorates due to corrosion or the like, and therefore there is concern that reliability of the semiconductor device may be degraded.

### BRIEF DESCRIPTION OF THE DRAWINGS

FIG. 1 shows a cross-sectional view showing a semiconductor device according to an embodiment.

FIG. 2 shows a partially enlarged cross-sectional view showing a portion of the semiconductor device according to the embodiment.

FIG. 3 shows a flowchart showing a step of manufacturing the semiconductor device according to the embodiment.

FIG. 4 shows a first partially enlarged cross-sectional view showing the step of manufacturing the semiconductor device according to the embodiment.

FIG. 5 shows a second partially enlarged cross-sectional view showing the step of manufacturing the semiconductor device according to the embodiment.

FIG. 6 shows a third partially enlarged cross-sectional view showing the step of manufacturing the semiconductor device according to the embodiment.

FIG. 7 shows a cross-sectional view showing a semiconductor device according to a first modification example of the embodiment.

FIG. 8 shows a cross-sectional view showing a semiconductor device according to a second modification example of the embodiment.

FIG. 9 shows a cross-sectional view showing a semiconductor device according to a third modification example of the embodiment.

FIG. 10 shows a partially enlarged cross-sectional view showing a portion of a semiconductor device according to a fourth modification example of the embodiment.

FIG. 11 shows a cross-sectional view showing a semiconductor device according to a fifth modification example of the embodiment.

FIG. 12 shows a cross-sectional view showing a semiconductor device according to a sixth modification example of the embodiment.

### DETAILED DESCRIPTION

According to one embodiment, a semiconductor device has a semiconductor chip. It has a terminal which is connected to the semiconductor chip and which comprises a first surface region containing copper. It has a functional film formed on at least a portion of a surface of the first surface region. The functional film covers at least the portion of the surface of the first surface region. Therefore, the functional film can be rephrased as function coat. It has a resin which covers a portion of the terminal and the semiconductor chip. The functional film comprises an organic film containing oxygen atoms. The organic film is bonded to the resin.

Hereinafter, a semiconductor device according to an embodiment will be described with reference to the drawings.

A Z-axis direction shown in each of the drawings is a vertical direction of the semiconductor device. A side that the arrow in the Z-axis direction faces (positive Z side) is an upward side of the semiconductor device. A side opposite to the side that the arrow in the Z-axis direction faces (negative Z side) is a downward side of the semiconductor device. In the following description, the upward side of the semiconductor device will be simply referred to as “an upward side”, the downward side of the semiconductor device will be simply referred to as “a downward side”, and the vertical direction of the semiconductor device will be simply referred to as “a vertical direction”. Each of the terms “the upward side”, “the downward side”, and “the vertical direction” does not indicate a relationship with the direction of gravity. In the following description, among outer surfaces of each member, each layer, and the like constituting the semiconductor device, a surface facing the upward side will be referred to as an upper surface, and a surface facing the downward side will be referred to as a lower surface.

A first direction D1 shown in each of the drawings is a direction orthogonal to the vertical direction. In the following description, a side that the arrow in the first direction D1 faces (positive D1 side) will be referred to as one side in the first direction D1, and a side opposite to the side that the arrow in the first direction D1 faces (negative D1 side) will be referred to as the other side in the first direction D1.

### Embodiment

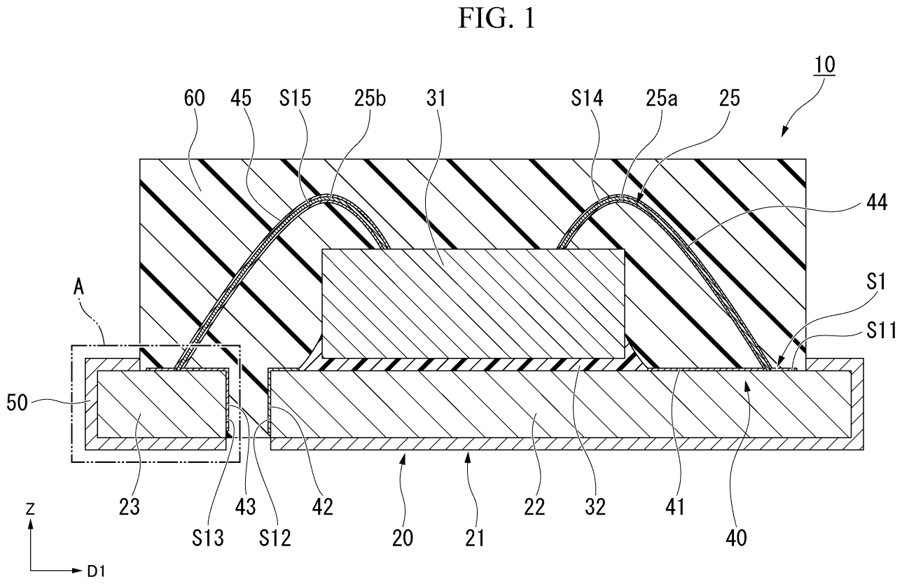

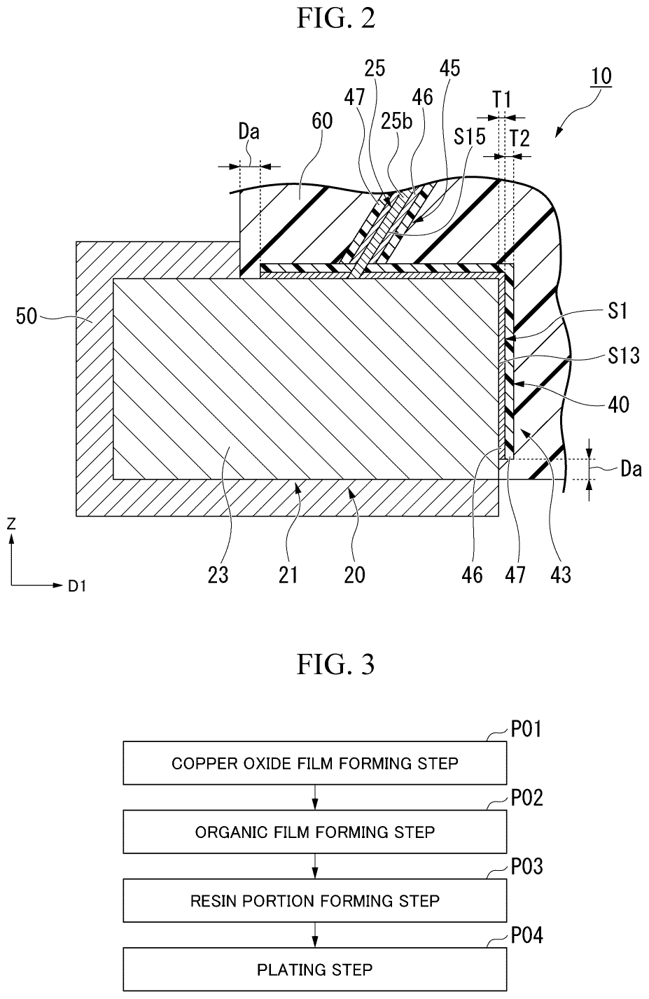

FIG. 1 shows a cross-sectional view showing a semiconductor device 10 according to the present embodiment. FIG. 2 shows a partially enlarged cross-sectional view showing a portion of the semiconductor device 10 according to the embodiment. FIG. 2 shows a part A in the semiconductor device 10 surrounded by a one-dot dashed line in FIG. 1. For example, the semiconductor device 10 according to the present embodiment is a semiconductor device such as a metal-oxide-semiconductor field-effect transistor (MOSFET) or an insulated gate bipolar transistor (IGBT). As shown in FIG. 1, the semiconductor device 10 according to the present embodiment includes a semiconductor chip 31, a terminal 20, and a resin 60.

The semiconductor chip 31 is formed of a semiconductor material. In the present embodiment, for example, silicon (Si), silicon carbide (SiC), gallium arsenide (GaAs), gallium nitride (GaN), or the like can be used as the semiconductor material constituting the semiconductor chip 31, but it is not limited thereto.

The terminal 20 electrically connects the semiconductor chip 31 to a power source (not shown) and a driven body (not shown) disposed outside the semiconductor device 10. Accordingly, power is supplied to the semiconductor chip 31 from the power source via the terminal 20. In addition, the semiconductor chip 31 can output power to the driven body via the terminal 20. In the present embodiment, both ends of the terminal 20 in the first direction D1 protrude from the resin 60. In the present embodiment, the terminal 20 includes a lead frame 21 and a wire 25.

The lead frame 21 has a plate shape extending in a direction orthogonal to the vertical direction. Both ends of the lead frame 21 in the first direction D1 protrude from the resin 60. The lead frame 21 is constituted using any one or more of copper, a copper-containing alloy, and a metal material other than copper having a copper-plated surface. That is, at least a portion of the terminal 20 is constituted using any one or more of copper, a copper-containing alloy, and a metal material other than copper having a copper-plated surface. In the present embodiment, the lead frame 21 is constituted using copper. Therefore, a surface region of the lead frame 21 contains copper. In the present embodiment, a part on a surface of the terminal 20 containing copper will be referred to as a first surface region S1. In the present embodiment, a part on the surface of the terminal 20 containing no copper will be referred to as a second surface region S2. At least a portion on the surface region of the lead frame 21 is the first surface region S1. In the present embodiment, the entire surface region of the lead frame 21 is the first surface region S1. A portion on the surface region of the lead frame 21 may be the second surface region S2. The lead frame 21 has a first lead frame 22 and a second lead frame 23.

The first lead frame 22 and the second lead frame 23 are disposed with a gap therebetween in the first direction D1. The first lead frame 22 is disposed on one side in the first direction D1 (positive D1 side) from the second lead frame 23. Each of the first lead frame 22 and the second lead frame 23 has a plate shape spreading in a direction orthogonal to the vertical direction.

The semiconductor chip 31 is fixed to the upper surface of the first lead frame 22 with a joining material 32 therebetween. For example, an insulating die-attach film having a known epoxy resin as a main component, a silver paste, a solder, a metal-sintered material such as copper or silver, or the like can be used as the joining material 32, but it is not limited thereto. The first lead frame 22 has a first surface region part S11 and a second surface region part S12.

The first surface region part S11 is a part on one side in the first direction D1 (positive D1 side) from the joining material 32 of the upper surface of the first lead frame 22. An end portion on the first surface region part S11 on one side in the first direction D1 is positioned on the other side in the first direction D1 (negative D1 side) from an end portion of the first lead frame 22 on one side in the first direction D1. The first surface region part S11 is the first surface region S1. The first surface region part S11 is covered by the resin 60.

The second surface region part S12 includes a part on the other side in the first direction D1 (negative D1 side) from the joining material 32 on the upper surface of the first lead frame 22, and a surface facing the other side of the first lead frame 22 in the first direction D1. The second surface region part S12 is the first surface region S1. The second surface region part S12 is covered by the resin 60.

The second lead frame 23 has a third surface region part S13. The third surface region part S13 includes a part on one side in the first direction D1 (positive D1 side) on the upper surface of the second lead frame 23, and a surface facing one side of the second lead frame 23 in the first direction D1. The third surface region part S13 is the first surface region S1. The third surface region part S13 is covered by the resin 60.

A plated layer 50 is formed in parts on the surface of the first lead frame 22 and the surface of the second lead frame 23 positioned outside the resin 60. That is, the plated layer 50 is formed in parts on the surface of the lead frame 21 positioned outside the resin 60. The plated layer 50 curbs contact between the parts on the surface of the lead frame 21 positioned outside the resin 60 and the outside air. Accordingly, deterioration due to corrosion or the like in the parts on the surface of the lead frame 21 positioned outside the resin 60 can be curbed. Therefore, reliability of the semiconductor device 10 can be enhanced. A metal material such as tin or nickel can be used as a material constituting the plated layer 50, but it is not limited thereto.

The wire 25 connects the lead frame 21 and the semiconductor chip 31 to each other. More specifically, the wire 25 connects an electrode (not shown) provided in the lead frame 21 and an electrode (not shown) provided in the semiconductor chip 31 to each other. When no electrode is provided in the lead frame 21, the wire 25 may be connected to the lead frame 21. In the present embodiment, the wire 25 is constituted using any one or more of copper, a copper-containing alloy, and a metal material other than copper having a copper-plated surface. That is, at least a portion of the terminal 20 is constituted using any one or more of copper, a copper-containing alloy, and a metal material other than copper having a copper-plated surface. In the present embodiment, the wire 25 is constituted using copper. In the present embodiment, a surface region of the wire 25 is the first surface region S1. The wire 25 includes a first wire 25a and a second wire 25b.

The first wire 25a connects the first lead frame 22 and the semiconductor chip 31 to each other. More specifically, one end of the first wire 25a is connected to the electrode (not shown) provided in the semiconductor chip 31, and the other end of the first wire 25a is connected to an electrode (not shown) provided in the first surface region part S11 of the first lead frame 22. A fourth surface region part S14 that is a surface of the first wire 25a contains copper. The fourth surface region part S14 is the first surface region S1. The fourth surface region part S14 is covered by the resin 60.

The second wire 25b connects the second lead frame 23 and the semiconductor chip 31 to each other. More specifically, one end of the second wire 25b is connected to the electrode (not shown) provided in the semiconductor chip 31, and the other end of the second wire 25b is connected to an electrode (not shown) provided in the third surface region part S13 of the second lead frame 23. A fifth surface region part S15 that is a surface of the second wire 25b contains copper. The fifth surface region part S15 is the first surface region S1. The fifth surface region part S15 is covered by the resin 60. As described above, the fourth surface region part S14 of the first wire 25a is the first surface region S1. Therefore, at least a portion on the surface region of the wire 25 is the first surface region S1. In the present embodiment, the entire surface region of the wire 25 is the first surface region S1. A portion on the surface region of the wire 25 may be the second surface region S2. In addition, as described above, at least a portion on the surface region of the lead frame 21 is the first surface region S1. Therefore, at least a portion on the surface of the terminal 20 is the first surface region S1.

In the present embodiment, a functional film 40 is formed in at least a portion of the part on the first surface region S1 of the terminal 20 covered by the resin 60. More specifically, in the present embodiment, the functional film 40 is formed in each of the first surface region part S11, the second surface region part S12, the third surface region part S13, the fourth surface region part S14, and the fifth surface region part S15 retained in the terminal 20. The outer surface of the functional film 40 comes into contact with the resin 60. In the present embodiment, the functional film 40 includes a first functional film portion 41, a second functional film portion 42, a third functional film portion 43, a fourth functional film portion 44, and a fifth functional film portion 45.

The first functional film portion 41 is formed in the first surface region part S11 of the terminal 20. The second functional film portion 42 is formed in the second surface region part S12. The third functional film portion 43 is formed in the third surface region part S13. The fourth functional film portion 44 is formed in the fourth surface region part S14. The fifth functional film portion 45 is formed in the fifth surface region part S15. As shown in FIG. 2, the functional film 40 comprises a copper oxide film 46 and an organic film 47. In the following description, only the constitutions or the like of the third functional film portion 43 and the fifth functional film portion 45 in the functional film 40 may be described. However, the constitution or the like other than the shape of each of the first functional film portion 41, the second functional film portion 42, and the fourth functional film portion 44 is similar to the constitution or the like other than the shape of the third functional film portion 43.

The copper oxide film 46 retained in the third functional film portion 43 is formed in the third surface region part S13. The copper oxide film 46 retained in the fifth functional film portion 45 is formed in the fifth surface region part S15. The copper oxide film 46 is formed in the part on the first surface region S1 covered by the resin 60. The copper oxide film 46 is formed between the first surface region S1 and the organic film 47. The copper oxide film 46 is constituted using copper oxide. The copper oxide film 46 is firmly bonded to the first surface region S1. In the present embodiment, since each of the copper oxide film 46 and the first surface region S1 contains copper, a bonding force between the copper oxide film 46 and the first surface region S1 can be enhanced.

In the present embodiment, the copper oxide film 46 is formed by oxidizing the surface of the terminal 20, that is, each of the lead frame 21 and the wire 25. That is, the copper oxide film 46 is formed by oxidizing the first surface region S1 of the terminal 20. A method for forming the copper oxide film 46 is not particularly limited, for example, the terminal 20 may be heated, or the terminal 20 may be left alone in an ordinary temperature atmosphere. In the present embodiment, a thickness T1 of the copper oxide film 46 is 1 nm to 15 nm. The functional film 40 may not comprise the copper oxide film 46. In this case, the functional film 40 comprises only the organic film 47, and the organic film 47 is formed on the first surface region S1.

The organic film 47 is formed on the copper oxide film 46. The organic film 47 is an organic film containing oxygen atoms. The organic film 47 is firmly bonded to the copper oxide film 46. In the present embodiment, since each of the organic film 47 and the copper oxide film 46 contains oxygen atoms, the organic film 47 and the copper oxide film 46 are bonded by covalent bonds via oxygen atoms. For this reason, in the present embodiment, a bonding force between the organic film 47 and the copper oxide film 46 can be enhanced. In the present embodiment, the organic film 47 is formed by immersing the terminal 20 in which the copper oxide film 46 is formed, that is, each of the lead frame 21 and the wire 25 in which the copper oxide film 46 is formed in an aqueous solution including azole-based organic matter. Since azole-based organic matter selectively reacts with copper, the organic film 47 is formed on only the copper oxide film 46 and is not formed on a surface of the material containing no copper. A method for forming the organic film 47 on the copper oxide film 46 may be a different method. In the present embodiment, a thickness T2 of the organic film 47 is 10 nm to 200 nm. It is preferable that the thickness T2 of the organic film 47 be 10 nm to 60 nm.

As shown in FIG. 1, the resin 60 covers a portion of the terminal 20 and the semiconductor chip 31. The resin 60 seals the first surface region part S11, the second surface region part S12, the third surface region part S13, the fourth surface region part S14, the fifth surface region part S15, and the surface of the semiconductor chip 31 from the outside air. The resin 60 seals the parts on the surface of the terminal 20 where the plated layer 50 is not formed from the outside air. Therefore, deterioration due to corrosion or the like in the parts on the surface of the terminal 20 where the plated layer 50 is not formed can be curbed. For example, a known epoxy resin, a UV curable resin, a thermosetting resin, or the like can be used as the resin 60, but it is not limited thereto. In the present embodiment, the resin 60 is constituted using an epoxy resin. As shown in FIG. 2, a portion of the resin 60 is firmly bonded to the functional film 40 formed on the first surface region S1 of the terminal 20. More specifically, a portion of the resin 60 is firmly bonded to the organic film 47. In the present embodiment, the resin 60 is bonded to the organic film 47 by covalent bonds via carbon atoms. Accordingly, in the present embodiment, a bonding force between the resin 60 and the organic film 47 can be enhanced. Namely, a bonding force between the resin 60 and the functional film 40 can be enhanced.

An end portion of the third functional film portion 43 on the downward side is positioned above an end portion of the resin 60 on the downward side. In addition, an end portion of the third functional film portion 43 on the other side in the first direction D1 (negative D1 side) is positioned on one side in the first direction D1 (positive D1 side) from an end portion of the resin 60 on the other side in the first direction D1. Accordingly, a gap is provided between the third functional film portion 43 and the plated layer 50. Similarly, as shown in FIG. 1, a gap is provided between each of the first functional film portion 41 and the second functional film portion 42, and the plated layer 50. That is, a gap is provided between the functional film 40 and the plated layer 50. An end portion of the functional film 40 is positioned on an inward side of the resin 60 from the end portion of the resin 60. As shown in FIG. 2, it is preferable that a distance Da between the functional film 40 and the plated layer 50 be 50 μm or longer. As will be described below in detail, this allows the plated layer 50 to be formed throughout the entire part on the surface of the lead frame 21 not covered by the resin 60. In the present embodiment, the distance Da between the functional film 40 and the plated layer 50 is 100 μm or longer. It is preferable that the distance Da between the functional film 40 and the plated layer 50 be 200 μm or shorter. Accordingly, since a situation in which a direct contact part between the terminal 20 and the resin 60 becomes excessively wide can be curbed, a situation in which the resin 60 peels off from the terminal 20 can be favorably curbed.

FIG. 3 shows a flowchart showing a step of manufacturing the semiconductor device 10. The step of manufacturing the semiconductor device 10 according to the present embodiment includes a copper oxide film forming step P01, an organic film forming step P02, a resin forming step P03, and a plating step P04. Although description will be omitted, the step of manufacturing the semiconductor device 10 has other steps such as a step of fixing the semiconductor chip 31 to the lead frame 21, for example.

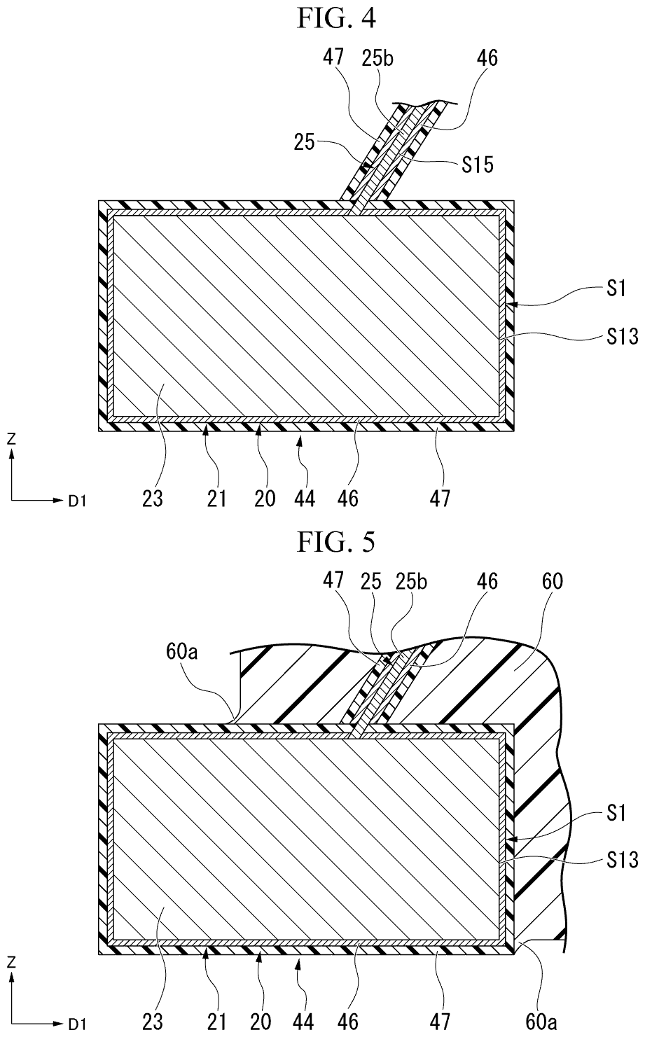

As shown in FIG. 4, the copper oxide film forming step P01 is a step of forming the copper oxide film 46 on the first surface region S1 of the terminal 20. In the present embodiment, the copper oxide film 46 is formed on the entire first surface region S1 of the terminal 20 in which the wire 25 is connected to an electrode (not shown) of the lead frame 21 in advance. As described above, in the present embodiment, the copper oxide film 46 is formed by oxidizing the first surface region S1 of the terminal 20. As described above, the method for forming the copper oxide film 46 is not particularly limited, for example, the terminal 20 may be heated, or the terminal 20 may be left alone in an ordinary temperature atmosphere.

The organic film forming step P02 is a step of forming the organic film 47 on the copper oxide film 46. As described above, in the present embodiment, the organic film 47 is formed on the copper oxide film 46 by immersing the terminal 20 in which the copper oxide film 46 is formed in an aqueous solution including azole-based organic matter. Accordingly, the functional film 40 is formed on the entire first surface region S1 of the terminal 20. At this time, as described above, the copper oxide film 46 and the organic film 47 are bonded by covalent bonds via oxygen atoms. In addition, as described above, since azole-based organic matter selectively reacts with copper, the organic film 47 is formed on only the copper oxide film 46 and is not formed on a surface of the material containing no copper. The method for forming the organic film 47 on the copper oxide film 46 may be a different method.

As shown in FIG. 5, the resin forming step P03 is a step of forming the resin 60. In the present embodiment, by a mold method using a transfer mold or the like, as shown in FIG. 1, the resin 60 is formed by curing the resin 60 through heating, for example, after a portion of the lead frame 21 and the semiconductor chip 31 are covered by the resin 60. As described above, the resin 60 is bonded to the organic film 47 retained in the functional film 40 by covalent bonds via carbon. As shown in FIG. 5, resin burrs 60a are formed in the resin 60. The resin burrs 60a protrude from the resin 60.

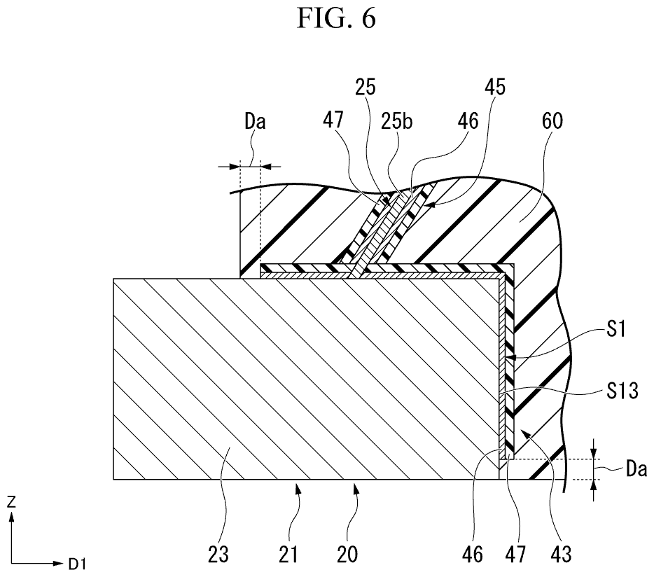

The plating step P04 is a step of forming the plated layer 50 constituted using tin in a part on the surface of the lead frame 21 not covered by the resin 60. In the plating step P04, first, the lead frame 21 is immersed in an acidic chemical solution to remove the functional film 40 formed in the part on the surface of the lead frame 21 not covered by the resin 60, as shown in FIG. 6. At this time, the resin burrs 60a are removed together with the functional film 40. In addition, the chemical solution permeates into the resin 60 from the end portion of the resin 60. In the present embodiment, the chemical solution permeates into the resin 60 from the end portion of the resin 60 by 100 μm or more. Accordingly, since the functional film 40 formed in the vicinity of the end portion of the resin 60 is removed, the end portion of the functional film 40 is positioned on the inward side of the resin 60 from the end portion of the resin 60 by 100 μm or more. The chemical solution is not limited to the chemical solution described above and may be an alkaline chemical solution. Thereafter, the lead frame 21 is subjected to plating treatment. Consequently, as shown in FIGS. 1 and 2, the plated layer 50 is formed in the part on the surface of the lead frame 21 not covered by the resin 60. If the plating step P04 ends, the step of manufacturing the semiconductor device 10 ends.

According to the present embodiment, the semiconductor device 10 includes the semiconductor chip 31, the terminal 20 which is connected to the semiconductor chip 31 and of which at least a portion on a surface is the first surface region S1 containing copper, and the resin 60 which covers a portion of the terminal 20 and the semiconductor chip 31. The functional film 40 comprising the organic film 47 containing oxygen atoms is formed in at least a portion of the part on the first surface region S1 covered by the resin 60, and the organic film 47 is bonded to the resin 60. Accordingly, as described above, since the organic film 47 and the resin 60 are bonded by covalent bonds via carbon atoms, a bonding force between the functional film 40 and the resin 60 can be enhanced. Therefore, a bonding force between the terminal 20 and the resin 60 can be enhanced with the functional film 40 therebetween. Accordingly, since a situation in which the resin 60 peels off from the terminal 20 can be curbed, contact between the terminal 20 and the outside air can be curbed. Therefore, since deterioration due to corrosion or the like in the terminal 20 can be curbed, reliability of the semiconductor device 10 can be enhanced.

According to the present embodiment, the functional film 40 comprises the copper oxide film 46 constituted using copper oxide between the first surface region S1 and the organic film 47, and the copper oxide film 46 is firmly bonded to the first surface region S1. Since each of the copper oxide film 46 and the first surface region S1 of the terminal 20 contains copper, a bonding force between the copper oxide film 46 and the first surface region S1 is greater than a bonding force between the organic film 47 and the first surface region S1. Moreover, as described above, since each of the copper oxide film 46 and the organic film 47 contains oxygen atoms, the copper oxide film 46 and the organic film 47 are bonded by covalent bonds via oxygen atoms. Therefore, a bonding force between the copper oxide film 46 and the organic film 47 can be enhanced. With these, compared to when the functional film 40 does not comprise the copper oxide film 46, a bonding force between the terminal 20 and the resin 60 can be more favorably enhanced with the functional film 40 therebetween. Thus, since a situation in which the resin 60 peels off from the terminal 20 can be more favorably curbed, deterioration due to corrosion or the like in the terminal 20 can be more favorably curbed. Therefore, reliability of the semiconductor device 10 can be more favorably enhanced.

According to the present embodiment, the thickness T1 of the copper oxide film 46 is 1 nm to 15 nm.

When the thickness T1 of the copper oxide film 46 is smaller than 1 nm, since the thickness T1 of the copper oxide film 46 becomes excessively small, a portion on the first surface region S1 of the terminal 20 may be exposed from the copper oxide film 46 due to surface roughness of the terminal 20, variation in the thickness T1 of the copper oxide film 46, or the like. In this case, since a portion on the first surface region S1 directly comes into contact with the organic film 47, a bonding force between the terminal 20 and the functional film 40 is degraded. Accordingly, since the functional film 40 is likely to peel off from the terminal 20, there is concern that a bonding force between the terminal 20 and the resin 60 with the functional film 40 therebetween may be degraded.

When the thickness T1 of the copper oxide film 46 is larger than 15 nm, since the thickness T1 of the copper oxide film 46 becomes excessively large, the copper oxide film 46 is likely to peel off from the terminal 20. Therefore, there is concern that a bonding force between the terminal 20 and the resin 60 with the functional film 40 therebetween may be degraded.

In contrast, in the present embodiment, as described above, the thickness T1 of the copper oxide film 46 is 1 nm to 15 nm. Thus, since a situation in which the thickness T1 of the copper oxide film 46 becomes excessively small can be curbed, exposure of a portion on the first surface region S1 from the copper oxide film 46 can be curbed. Accordingly, degradation in bonding force between the terminal 20 and the functional film 40 can be curbed. In addition, since a situation in which the thickness T1 of the copper oxide film 46 becomes excessively large can be curbed, a situation in which the copper oxide film 46 peels off from the terminal 20 can be curbed. With these, since degradation in bonding force between the terminal 20 and the resin 60 with the functional film 40 therebetween can be curbed, a situation in which the resin 60 peels off from the terminal 20 can be more favorably curbed. Therefore, reliability of the semiconductor device 10 can be more favorably enhanced.

According to the present embodiment, the thickness T2 of the organic film 47 is 10 nm to 200 nm.

When the thickness T2 of the organic film 47 is smaller than 10 nm, since the thickness T2 of the organic film 47 becomes excessively small, variation in the thickness T2 of the organic film 47 is likely to increase. Accordingly, a portion of the copper oxide film 46 may be exposed from the organic film 47. In this case, since a portion of the copper oxide film 46 directly comes into contact with the resin 60, the contact area between the organic film 47 and the resin 60 is degraded. Thus, a bonding force between the functional film 40 and the resin 60 is degraded. Accordingly, since the resin 60 is likely to peel off from the functional film 40, there is concern that a bonding force between the terminal 20 and the resin 60 with the functional film 40 therebetween may be degraded.

When the thickness T2 of the organic film 47 is larger than 200 nm, since the thickness T2 of the organic film 47 becomes excessively large, there is concern that man-hours for forming the organic film 47 in the organic film forming step P02 may increase.

In contrast, in the present embodiment, as described above, the thickness T2 of the organic film 47 is 10 nm to 200 nm. Thus, since a situation in which the thickness T2 of the organic film 47 becomes excessively small can be curbed, variation in the thickness T2 of the organic film 47 can be curbed. Accordingly, since exposure of a portion of the copper oxide film 46 from the organic film 47 can be curbed, degradation in contact area between the organic film 47 and the resin 60 can be curbed. Therefore, since degradation in bonding force between the functional film 40 and the resin 60 can be curbed, a bonding force between the terminal 20 and the resin 60 with the functional film 40 therebetween can be more favorably enhanced. In addition, since a situation in which the thickness T2 of the organic film 47 becomes excessively large can be curbed, increase in man-hours for forming the organic film 47 in the organic film forming step P02 can be curbed.

According to the present embodiment, the thickness T2 of the organic film 47 is 10 nm to 60 nm. Thus, since a situation in which the thickness T2 of the organic film 47 becomes excessively small can be more favorably curbed, variation in the thickness T2 of the organic film 47 can be more favorably curbed. Accordingly, since exposure of a portion of the copper oxide film 46 from the organic film 47 can be more favorably curbed, degradation in contact area between the organic film 47 and the resin 60 can be more favorably curbed. Therefore, a bonding force between the terminal 20 and the resin 60 with the functional film 40 therebetween can be more favorably enhanced. In addition, since a situation in which the thickness T2 of the organic film 47 becomes excessively large can be more favorably curbed, increase in man-hours for forming the organic film 47 in the organic film forming step P02 can be more favorably curbed.

According to the present embodiment, at least a portion of the terminal 20 is constituted using any one or more of copper, a copper-containing alloy, and a metal material other than copper having a copper-plated surface. For this reason, in the copper oxide film forming step P01, the copper oxide film 46 can be formed on the first surface region S1 by simple work of oxidizing the first surface region S1 of the terminal 20. Accordingly, for example, the copper oxide film 46 can be formed more easily than when the copper oxide film 46 is formed on the first surface region S1 of the terminal 20 by a different method such as a physical vapor deposition method or a chemical vapor deposition method. Therefore, increase in man-hours for forming the copper oxide film 46 in the copper oxide film forming step P01 can be curbed.

According to the present embodiment, the terminal 20 includes the lead frame 21, and the wire 25 connecting the lead frame 21 and the semiconductor chip 31 to each other. At least a portion of each of the surface region of the lead frame 21 and the surface region of the wire 25 is the first surface region S1. Thus, the functional film 40 can be formed on each of the first surface region S1 of the lead frame 21 and the first surface region S1 of the wire 25. For this reason, a bonding force between each of the lead frame 21 and the wire 25 and the resin 60 can be enhanced with the functional film 40 therebetween. Accordingly, since a situation in which the resin 60 peels off from each of the lead frame 21 and the wire 25 can be curbed, contact between each of the lead frame 21 and the wire 25 and the outside air can be curbed. Therefore, since deterioration due to corrosion or the like in each of the lead frame 21 and the wire 25 can be curbed, reliability of the semiconductor device 10 can be enhanced.

According to the present embodiment, the plated layer 50 is formed in the parts on the surface of the lead frame 21 positioned outside the resin 60, and the distance Da between the functional film 40 and the plated layer 50 is 100 μm or longer. Thus, in the plating step P04, since the functional film 40 formed in the part on the surface of the lead frame 21 not covered by the resin 60 can be removed, the plated layer 50 can be formed throughout the entire part on the surface of the lead frame 21 not covered by the resin 60. Accordingly, contact between the lead frame 21 and the outside air can be more favorably curbed. Therefore, since deterioration due to corrosion or the like in the lead frame 21 can be more favorably curbed, reliability of the semiconductor device 10 can be more favorably enhanced.

### First Modification Example

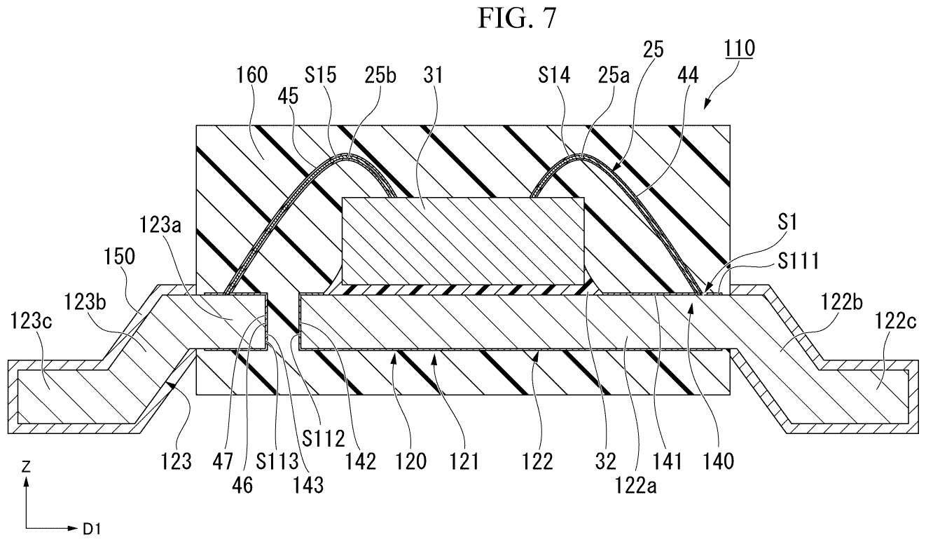

FIG. 7 shows a cross-sectional view showing a semiconductor device 110 according to a first modification example of the embodiment. In the semiconductor device 110 according to the present modification example, the shape of a lead frame 121 is a shape different from the shape of the lead frame 21 according to the embodiment described above. In the following description, the same reference signs are applied to constituent elements having the same form as those in the embodiment described above, and description thereof will be omitted. The semiconductor device 110 according to the present modification example includes the semiconductor chip 31, a terminal 120, and a resin 160.

The terminal 120 electrically connects the semiconductor chip 31 to a power source (not shown) and a driven body (not shown) disposed outside the semiconductor device 110. In the present modification example, both ends of the terminal 120 in the first direction D1 protrude from the resin 160. In the present modification example, the terminal 120 includes the lead frame 121 and the wire 25.

Both ends of the lead frame 121 in the first direction D1 protrude from the resin 160. In the present modification example, the lead frame 121 is constituted using copper. At least a portion on a surface region of the lead frame 121 is the first surface region S1. In the present modification example, the entire surface region of the lead frame 121 is the first surface region S1. The lead frame 121 has a first lead frame 122 and a second lead frame 123. The first lead frame 122 and the second lead frame 123 are disposed with a gap therebetween in the first direction D1. The first lead frame 122 is disposed on one side in the first direction D1 (positive D1 side) from the second lead frame 123.

The first lead frame 122 has a first part 122a, a second part 122b, and a third part 122c. The first part 122a has a plate shape spreading in a direction orthogonal to the vertical direction. The semiconductor chip 31 is fixed to the upper surface of the first part 122a with the joining material 32 therebetween. A portion of the first part 122a is positioned inside the resin 160. An end portion of the first part 122a on one side in the first direction D1 (positive D1 side) protrudes to the outside of the resin 160. The second part 122b has a plate shape positioned on the downward side as it goes toward one side in the first direction D1. An end portion of the second part 122b on the other side in the first direction D1 (negative D1 side) leads to the end portion of the first part 122a on one side in the first direction D1. The third part 122c has a plate shape spreading in a direction orthogonal to the vertical direction. An end portion of the third part 122c on the other side in the first direction D1 leads to an end portion of the second part 122b on one side in the first direction D1. The second part 122b and the third part 122c are positioned on an outward side of the resin 160. The first lead frame 122 has a first surface region part S111 and a second surface region part S112.

The first surface region part S111 is a part on one side in the first direction D1 (positive D1 side) from the joining material 32 on the upper surface of the first part 122a. An end portion on the first surface region part S111 on one side in the first direction D1 is positioned on the other side in the first direction D1 (negative D1 side) from the end portion of the first part 122a on one side in the first direction D1. The first surface region part S111 is the first surface region S1. The first surface region part S111 is covered by the resin 160.

The second surface region part S112 includes a part on the other side in the first direction D1 (negative D1 side) from the joining material 32 on the upper surface of the first part 122a, a surface facing the other side of the first part 122a in the first direction D1, and a lower surface of the first part 122a. The second surface region part S112 is the first surface region S1. The second surface region part S112 is covered by the resin 160.

The second lead frame 123 has a fourth part 123a, a fifth part 123b, and a sixth part 123c. The fourth part 123a has a plate shape spreading in a direction orthogonal to the vertical direction. A portion of the fourth part 123a is positioned inside the resin 160. An end portion of the fourth part 123a on the other side in the first direction D1 (negative D1 side) protrudes to the outside of the resin 160. The fifth part 123b has a plate shape positioned on the downward side as it goes toward the other side in the first direction D1. An end portion of the fifth part 123b on one side in the first direction D1 (positive D1 side) leads to the end portion of the fourth part 123a on the other side in the first direction D1. The sixth part 123c has a plate shape spreading in a direction orthogonal to the vertical direction. An end portion of the sixth part 123c on one side in the first direction D1 leads to an end portion of the fifth part 123b on the other side in the first direction D1. The fifth part 123b and the sixth part 123c are positioned on the outward side of the resin 160. The second lead frame 123 has a third surface region part S113.

The third surface region part S113 includes a part on one side in the first direction D1 (positive D1 side) on the upper surface of the fourth part 123a, a surface facing one side of the fourth part 123a in the first direction D1, and a lower surface of the fourth part 123a. The third surface region part S113 is the first surface region S1. The third surface region part S113 is covered by the resin 160. A plated layer 150 is formed in parts on the surface of the lead frame 121 positioned outside the resin 160. Other constitutions and the like of the terminal 120 according to the present modification example are similar to other constitutions and the like of the terminal 20 according to the embodiment described above.

In the present modification example, a functional film 140 is formed in at least a portion of the part on the first surface region S1 of the terminal 120 covered by the resin 160. In the present modification example, the functional film 140 is formed in each of the first surface region part S111, the second surface region part S112, the third surface region part S113, the fourth surface region part S14, and the fifth surface region part S15. The outer surface of the functional film 140 comes into contact with the resin 160. In the present modification example, the functional film 140 includes a first functional film portion 141, a second functional film portion 142, a third functional film portion 143, the fourth functional film portion 44, and the fifth functional film portion 45.

The first functional film portion 141 is formed in the first surface region part S111. The second functional film portion 142 is formed in the second surface region part S112. The third functional film portion 143 is formed in the third surface region part S113. The fourth functional film portion 44 is formed in the fourth surface region part S14. The fifth functional film portion 45 is formed in the fifth surface region part S15. Similar to the functional film 40 according to the embodiment described above, the functional film 140 comprises the copper oxide film 46 and the organic film 47. The copper oxide film 46 is formed in a part on the first surface region S1 covered by the resin 160. The copper oxide film 46 is firmly bonded to the first surface region S1. The organic film 47 is formed on the copper oxide film 46. The organic film 47 is an organic film containing oxygen atoms. The organic film 47 is firmly bonded to the copper oxide film 46. Other constitutions and the like of the functional film 140 according to the present modification example are similar to other constitutions and the like of the functional film 40 according to the embodiment described above.

The resin 160 covers a portion of the terminal 120, and the semiconductor chip 31. The resin 160 seals the first surface region part S111, the second surface region part S112, the third surface region part S113, the fourth surface region part S14, the fifth surface region part S15, and the surface of the semiconductor chip 31 from the outside air. Therefore, deterioration due to corrosion or the like in the parts on the surface of the terminal 120 where the plated layer 50 is not formed can be curbed. A portion of the resin 160 is firmly bonded to the functional film 140 formed on the first surface region S1 of the terminal 120. More specifically, a portion of the resin 160 is firmly bonded to the organic film 47. In the present modification example, the resin 160 is bonded to the organic film 47 by covalent bonds via carbon atoms. Other constitutions and the like of the resin 160 according to the present modification example are similar to other constitutions and the like of the resin 60 according to the embodiment described above.

According to the present modification example, the functional film 140 comprising the organic film 47 containing oxygen atoms is formed in at least a portion of the part on the first surface region S1 of the terminal 120 covered by the resin 160, and the organic film 47 is bonded to the resin 160. Accordingly, similar to the embodiment described above, since the organic film 47 and the resin 60 are bonded by covalent bonds via carbon atoms, a bonding force between the functional film 140 and the resin 160 can be enhanced. Therefore, since a bonding force between the terminal 120 and the resin 160 can be enhanced with the functional film 140 therebetween, a situation in which the resin 160 peels off from the terminal 120 can be curbed. Therefore, since deterioration due to corrosion or the like in the terminal 120 can be curbed, reliability of the semiconductor device 110 can be enhanced.

According to the present modification example, the functional film 140 comprises the copper oxide film 46 constituted using copper oxide between the first surface region S1 and the organic film 47, and the copper oxide film 46 is firmly bonded to the first surface region S1. For this reason, similar to the embodiment described above, a bonding force between the terminal 120 and the resin 160 can be more favorably enhanced with the functional film 140 therebetween. Therefore, a situation in which the resin 160 peels off from the terminal 120 can be more favorably curbed.

### Second Modification Example

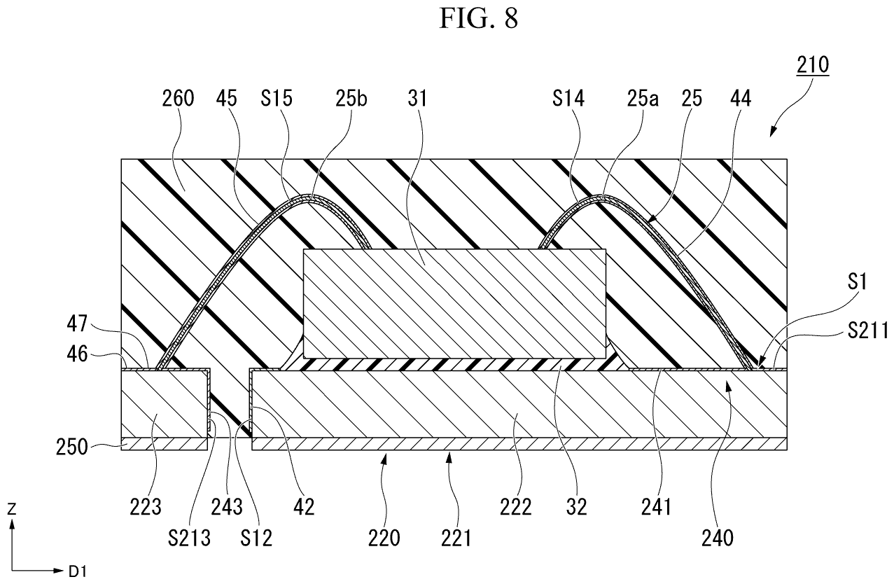

FIG. 8 shows a cross-sectional view showing a semiconductor device 210 according to a second modification example of the embodiment. In the semiconductor device 210 according to the present modification example, the shape of a lead frame 221 is a shape different from the shape of the lead frame 21 according to the embodiment described above. In the following description, the same reference signs are applied to constituent elements having the same form as those in the embodiment described above, and description thereof will be omitted. The semiconductor device 210 according to the present modification example includes the semiconductor chip 31, a terminal 220, and a resin 260.

The terminal 220 electrically connects the semiconductor chip 31 to a power source (not shown) and a driven body (not shown) disposed outside the semiconductor device 210. In the present modification example, the terminal 220 includes the lead frame 221 and the wire 25.

In the first direction D1, both ends of the lead frame 221 in the first direction D1 are at positions substantially the same as both ends of the resin 260 in the first direction D1. In the present modification example, the lead frame 221 is constituted using copper. At least a portion on a surface region of the lead frame 221 is the first surface region S1. In the present modification example, the entire surface region of the lead frame 221 is the first surface region S1. The lead frame 221 has a first lead frame 222 and a second lead frame 223. The first lead frame 222 and the second lead frame 223 are disposed with a gap therebetween in the first direction D1. The first lead frame 222 is disposed on one side in the first direction D1 (positive D1 side) from the second lead frame 223.

The first lead frame 222 has a plate shape spreading in a direction orthogonal to the vertical direction. The semiconductor chip 31 is fixed to the upper surface of the first lead frame 222 with the joining material 32 therebetween. The first lead frame 222 has a first surface region part S211 and the second surface region part S12.

The first surface region part S211 is a part on one side in the first direction D1 (positive D1 side) from the joining material 32 on the upper surface of the first lead frame 222. The first surface region part S211 is the first surface region S1. The first surface region part S211 is covered by the resin 260.

The second lead frame 223 has a plate shape spreading in a direction orthogonal to the vertical direction. The second lead frame 223 has a third surface region part S213.

The third surface region part S213 includes an upper surface of the second lead frame 223, and a surface facing one side of the second lead frame 223 in the first direction D1. The third surface region part S213 is the first surface region S1. The third surface region part S213 is covered by the resin 260. A plated layer 250 is formed in parts on the surface of the lead frame 221 positioned outside the resin 260. Other constitutions and the like of the terminal 220 according to the present modification example are similar to other constitutions and the like of the terminal 20 according to the embodiment described above.

In the present modification example, a functional film 240 is formed in at least a portion of the part on the first surface region S1 of the terminal 220 covered by the resin 260. In the present modification example, the functional film 240 is formed in each of the first surface region part S211, the second surface region part S12, the third surface region part S213, the fourth surface region part S14, and the fifth surface region part S15. The outer surface of the functional film 240 comes into contact with the resin 260. In the present modification example, the functional film 240 includes a first functional film portion 241, the second functional film portion 42, a third functional film portion 243, the fourth functional film portion 44, and the fifth functional film portion 45.

The first functional film portion 241 is formed in the first surface region part S211. The second functional film portion 42 is formed in the second surface region part S12. The third functional film portion 243 is formed in the third surface region part S213. The fourth functional film portion 44 is formed in the fourth surface region part S14. The fifth functional film portion 45 is formed in the fifth surface region part S15. Similar to the functional film 40 according to the embodiment described above, the functional film 240 comprises the copper oxide film 46 and the organic film 47. The copper oxide film 46 is formed in a part on the first surface region S1 covered by the resin 260. The copper oxide film 46 is firmly bonded to the first surface region S1. The organic film 47 is formed on the copper oxide film 46. The organic film 47 is an organic film containing oxygen atoms. The organic film 47 is firmly bonded to the copper oxide film 46. Other constitutions and the like of the functional film 240 according to the present modification example are similar to other constitutions and the like of the functional film 40 according to the embodiment described above.

The resin 260 covers a portion of the terminal 220, and the semiconductor chip 31. The resin 260 seals the first surface region part S211, the second surface region part S12, the third surface region part S213, the fourth surface region part S14, the fifth surface region part S15, and the surface of the semiconductor chip 31 from the outside air. A portion of the resin 260 is firmly bonded to the functional film 240 formed on the first surface region S1 of the terminal 220. More specifically, a portion of the resin 260 is firmly bonded to the organic film 47. In the present modification example, the resin 260 is bonded to the organic film 47 by covalent bonds via carbon atoms. Other constitutions and the like of the resin 260 according to the present modification example are similar to other constitutions and the like of the resin 60 according to the embodiment described above.

According to the present modification example, the functional film 240 comprising the organic film 47 containing oxygen atoms is formed in at least a portion of the part on the first surface region S1 of the terminal 220 covered by the resin 260, and the organic film 47 is bonded to the resin 260. Accordingly, similar to the embodiment described above, since the organic film 47 and the resin 260 are bonded by covalent bonds via carbon atoms, a bonding force between the functional film 240 and the resin 260 can be enhanced. Therefore, since a bonding force between the terminal 220 and the resin 260 can be enhanced with the functional film 240 therebetween, a situation in which the resin 260 peels off from the terminal 220 can be curbed.

According to the present modification example, the functional film 240 comprises the copper oxide film 46 constituted using copper oxide between the first surface region S1 and the organic film 47, and the copper oxide film 46 is firmly bonded to the first surface region S1. For this reason, similar to the embodiment described above, a bonding force between the terminal 220 and the resin 260 can be more favorably enhanced with the functional film 240 therebetween. Therefore, a situation in which the resin 260 peels off from the terminal 220 can be more favorably curbed.

### Third Modification Example

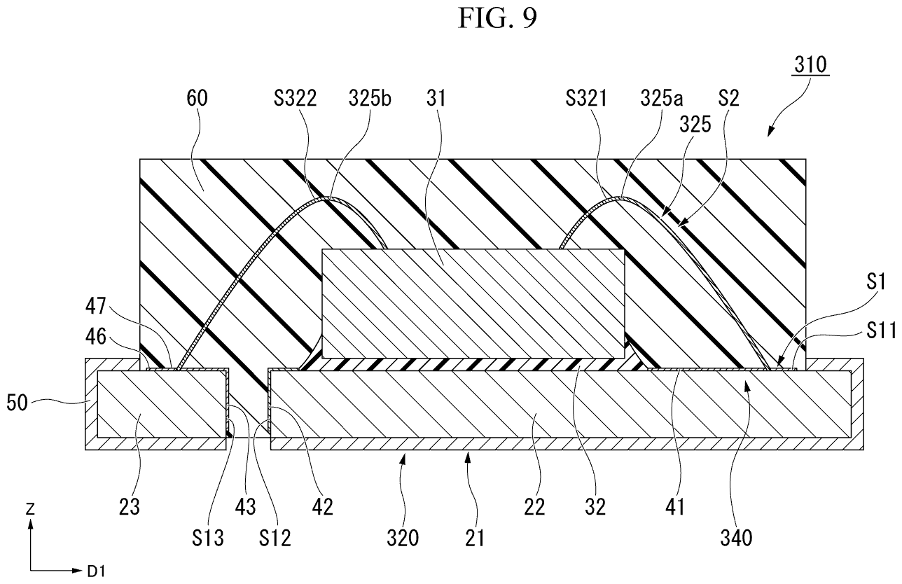

FIG. 9 shows a cross-sectional view showing a semiconductor device 310 according to a third modification example of the embodiment. In the semiconductor device 310 according to the present modification example, the material of a wire 325 is gold. In the following description, the same reference signs are applied to constituent elements having the same form as those in the embodiment described above, and description thereof will be omitted. The semiconductor device 310 according to the present modification example includes the semiconductor chip 31, a terminal 320, and the resin 60.

The terminal 320 electrically connects the semiconductor chip 31 to a power source (not shown) and a driven body (not shown) disposed outside the semiconductor device 310. In the present modification example, the terminal 320 includes the lead frame 21 and the wire 325.

The wire 325 connects the lead frame 21 and the semiconductor chip 31 to each other. More specifically, the wire 325 connects the electrode (not shown) provided in the lead frame 21 and the electrode (not shown) provided in the semiconductor chip 31 to each other. For example, a metal such as gold or silver can be used as a material constituting the wire 325, but it is not limited thereto. In the present modification example, the wire 325 is constituted using gold. For this reason, a surface region of the wire 325 is the second surface region S2 containing no copper. Similar to the embodiment described above, the surface region of the lead frame 21 is the first surface region S1. Therefore, at least a portion on a surface of the terminal 320 is the first surface region S1. The wire 325 includes a first wire 325a and a second wire 325b.

The first wire 325a connects the first lead frame 22 and the semiconductor chip 31 to each other. One end of the first wire 325a is connected to the electrode (not shown) provided in the semiconductor chip 31, and the other end of the first wire 325a is connected to the electrode (not shown) provided in the first surface region part S11 of the first lead frame 22. In the present modification example, a fourth surface region part S321 that is a surface of the first wire 325a is the second surface region S2 containing no copper. The fourth surface region part S321 is covered by the resin 60.

The second wire 325b connects the second lead frame 23 and the semiconductor chip 31 to each other. More specifically, one end of the second wire 325b is connected to the electrode (not shown) provided in the semiconductor chip 31, and the other end of the second wire 325b is connected to the electrode (not shown) provided in the third surface region part S13 of the second lead frame 23. In the present modification example, a fifth surface region part S322 that is a surface of the second wire 325b is the second surface region S2 containing no copper. The fifth surface region part S322 is covered by the resin 60. Other constitutions and the like of the terminal 320 according to the present modification example are similar to other constitutions and the like of the terminal 20 according to the embodiment described above.

In a step of manufacturing the semiconductor device 310 according to the present modification example, similar to the step of manufacturing the semiconductor device 10 according to the embodiment described above, a functional film 340 is formed on the first surface region S1 of the lead frame 21 by performing the copper oxide film forming step P01 and the organic film forming step P02 described above with respect to the terminal 320 in which the wire 325 is connected to the electrode (not shown) of the lead frame 21 in advance. In this case, in the organic film forming step P02, the organic film 47 is formed by immersing the terminal 320 in an aqueous solution including azole-based organic matter. As described above, since azole-based organic matter selectively reacts with copper, the organic film 47 is formed on only the copper oxide film 46 and is not formed on the fourth surface region part S321 and the fifth surface region part S322 retained in the wire 325 containing no copper. For this reason, in the present modification example, the functional film 340 is formed in at least a portion of the part on the first surface region S1 of the terminal 320 covered by the resin 60. In the present modification example, the functional film 340 is formed in each of the first surface region part S11, the second surface region part S12, and the third surface region part S13 retained in the lead frame 21. In the present modification example, the functional film 340 is not formed in each of the fourth surface region part S321 and the fifth surface region part S322 retained in the wire 325. That is, the functional film 340 is not formed on the surface of the second surface region S2 retained in the terminal 320. The outer surface of the functional film 340 comes into contact with the resin 60. In the present modification example, the functional film 340 includes the first functional film portion 41, the second functional film portion 42, and the third functional film portion 43.

The first functional film portion 41 is formed in the first surface region part S11. The second functional film portion 42 is formed in the second surface region part S12. The third functional film portion 43 is formed in the third surface region part S13. Although illustration is omitted, similar to the functional film 40 according to the embodiment described above, the functional film 340 comprises the copper oxide film 46 and the organic film 47. Other constitutions and the like of the functional film 340 according to the present modification example are similar to other constitutions and the like of the functional film 40 according to the embodiment described above.

The resin 60 covers a portion of the terminal 320, and the semiconductor chip 31. The resin 60 seals the first surface region part S11, the second surface region part S12, the third surface region part S13, the fourth surface region part S321, the fifth surface region part S322, and the surface of the semiconductor chip 31 from the outside air. A portion of the resin 60 is firmly bonded to the functional film 340 formed on the first surface region S1 of the lead frame 21. More specifically, a portion of the resin 60 is firmly bonded to the organic film 47. In the present modification example, the resin 60 is bonded to the organic film 47 by covalent bonds via carbon atoms.

According to the present modification example, the terminal 320 includes the lead frame 21, and the wire 325 connecting the lead frame 21 and the semiconductor chip 31 to each other. The surface region of the lead frame 21 is the first surface region S1, the surface region of the wire 325 is the second surface region S2 containing no copper, and the functional film 340 is not formed on the surface of the second surface region S2. Thus, since the functional film 340 can be formed on the surface of the lead frame 21, a bonding force between the lead frame 21 and the resin 60 can be enhanced with the functional film 340 therebetween. Accordingly, a situation in which the resin 60 peels off from the lead frame 21 can be curbed. Therefore, reliability of the semiconductor device 310 can be enhanced.

In addition, in the present modification example, for example, a precious metal such as gold or silver is used as a material constituting the wire 325. Therefore, for instance, even if the resin 60 peels off from the wire 325, deterioration due to corrosion or the like in the wire 325 can be curbed. Therefore, reliability of the semiconductor device 310 can be enhanced.

### Fourth Modification Example

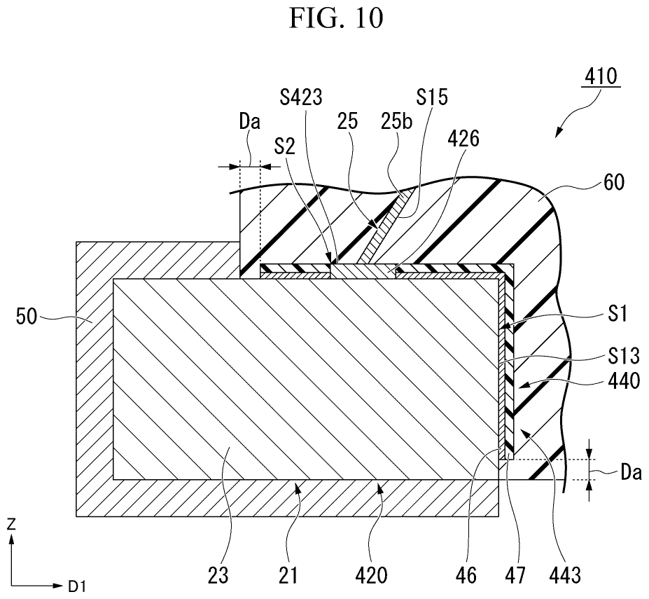

FIG. 10 shows a partially enlarged cross-sectional view showing a semiconductor device 410 according to a fourth modification example of the embodiment. In the semiconductor device 410 according to the present modification example, a terminal 420 includes an electrode portion 426. In the following description, the same reference signs are applied to constituent elements having the same form as those in the embodiment described above, and description thereof will be omitted. The semiconductor device 410 according to the present modification example includes the semiconductor chip 31, the terminal 420, and the resin 60.

The terminal 420 electrically connects the semiconductor chip 31 to a power source (not shown) and a driven body (not shown) disposed outside the semiconductor device 410. In the present modification example, the terminal 420 includes the lead frame 21, the wire 25, and the electrode portion 426.

The electrode portion 426 is formed on the surface of the lead frame 21. More specifically, the electrode portion 426 is formed on the upper surface of the second lead frame 23. The electrode portion 426 is formed in the third surface region part S13. For example, a metal such as gold or silver can be used as a material constituting the electrode portion 426, but it is not limited thereto. In the present modification example, the electrode portion 426 is constituted using silver. For this reason, a surface region of the electrode portion 426 is the second surface region S2 containing no copper. The electrode portion 426 is formed by plating the second lead frame 23. The other end of the second wire 25b is connected to a sixth surface region part S423 that is a surface on the surface of the electrode portion 426 facing the upward side. The sixth surface region part S423 is the second surface region S2. Similar to the embodiment described above, the surface region of the lead frame 21 is the first surface region S1. Therefore, at least a portion on a surface of the terminal 420 is the first surface region S1. Other constitutions and the like of the terminal 420 according to the present modification example are similar to other constitutions and the like of the terminal 20 according to the embodiment described above.

Although illustration is omitted, in the present modification example, the electrode portion 426 may be formed in each of the first surface region part S11 of the first lead frame 22 (refer to FIG. 1) and the upper surface of the semiconductor chip 31 (refer to FIG. 1). In this case, one end of the first wire 25a (refer to FIG. 1) and one end of the second wire 25b is connected to the electrode portion 426 formed on the upper surface of the semiconductor chip 31, and the other end of the first wire 25a is connected to the electrode portion 426 formed on the first surface region part S11.

In the present modification example, a functional film 440 is formed in at least a portion of the part on the first surface region S1 of the terminal 420 covered by the resin 60. In the present modification example, the functional film 440 is formed in each of the first surface region part S11 (refer to FIG. 1), the second surface region part S12 (refer to FIG. 1), and the third surface region part S13 retained in the lead frame 21. In the present modification example, the functional film 440 is not formed in each of the fourth surface region part S14 (refer to FIG. 1) and the fifth surface region part S15 retained in the wire 25. Moreover, in the present modification example, the functional film 440 is not formed in the sixth surface region part S423 retained in the electrode portion 426. That is, the functional film 440 is not formed on the surface of the second surface region S2 retained in the terminal 420. The outer surface of the functional film 440 comes into contact with the resin 60. In the present modification example, the functional film 440 includes the first functional film portion 41 (refer to FIG. 1), the second functional film portion 42 (refer to FIG. 1), and a third functional film portion 443.

The first functional film portion 41 is formed in the first surface region part S11 (refer to FIG. 1). The second functional film portion 42 is formed in the second surface region part S12 (refer to FIG. 1). The third functional film portion 443 is formed in a part of the third surface region part S13 excluding the part in which the electrode portion 426 is formed. The functional film 440 comprises the copper oxide film 46 and the organic film 47. Other constitutions and the like of the functional film 440 according to the present modification example are similar to other constitutions and the like of the functional film 40 according to the embodiment described above.

The resin 60 covers a portion of the terminal 420, and the semiconductor chip 31. The resin 60 seals the first surface region part S11, the second surface region part S12, the third surface region part S13, the fourth surface region part S14, the fifth surface region part S15, the sixth surface region part S423, and the surface of the semiconductor chip 31 from the outside air. A portion of the resin 60 is firmly bonded to the functional film 440 formed on the first surface region S1 of the terminal 420. More specifically, a portion of the resin 60 is firmly bonded to the organic film 47. In the present modification example, the resin 60 is bonded to the organic film 47 by covalent bonds via carbon atoms.

In a step of manufacturing the semiconductor device 410 according to the present modification example, the functional film 440 is formed on the first surface region S1 of the lead frame 21 by performing the copper oxide film forming step P01 and the organic film forming step P02 described above with respect to the lead frame 21 in which the electrode portion 426 is formed. In this case, in the organic film forming step P02, the organic film 47 is formed by immersing the lead frame 21 in which the electrode portion 426 is formed in an aqueous solution including azole-based organic matter. As described above, since azole-based organic matter selectively reacts with copper, the organic film 47 is formed on only the copper oxide film 46 and is not formed on the sixth surface region part S423 retained in the electrode portion 426 containing no copper. For this reason, when the wire 25 is connected to the electrode portion 426 in a step subsequent to the organic film forming step P02, the wire 25 and the electrode portion 426 can be directly connected to each other without performing work of removing the insulating functional film 40 from the sixth surface region part S423.

In addition, in the step of manufacturing the semiconductor device 410 according to the present modification example, in a step prior to the copper oxide film forming step P01 and the organic film forming step P02 described above, the wire 25 may be connected to the electrode portion 426. In this case as well, the wire 25 and the electrode portion 426 can be directly connected to each other.

According to the present modification example, the terminal 420 includes the electrode portion 426 formed on the surface of the lead frame 21, the electrode portion 426 comprises the second surface region S2 containing no copper, and the functional film 440 is not formed on the surface of the second surface region S2. Thus, as described above, even if the copper oxide film forming step P01 and the organic film forming step P02 are performed with respect to the lead frame 21 in which the electrode portion 426 is formed, the functional film 440 is not formed on the surface of the electrode portion 426. For this reason, even when the wire 25 is connected to the electrode portion 426 after the functional film 440 is formed in the lead frame 21 in the copper oxide film forming step P01 and the organic film forming step P02, the wire 25 and the electrode portion 426 can be directly connected to each other without performing work of removing the insulating functional film 440 from the surface of the electrode portion 426. Therefore, increase in man-hours for connecting the wire 25 to the electrode portion 426 can be curbed.

In addition, in the present modification example, as described above, the wire 25 and the electrode portion 426 can be directly connected to each other in both cases when the wire 25 is connected to the electrode portion 426 in a step prior to the copper oxide film forming step P01 and the organic film forming step P02 and when the wire 25 is connected to the electrode portion 426 in a step subsequent to the copper oxide film forming step P01 and the organic film forming step P02. Therefore, the degree of freedom in the step of manufacturing the semiconductor device 410 can be enhanced.

### Fifth Modification Example

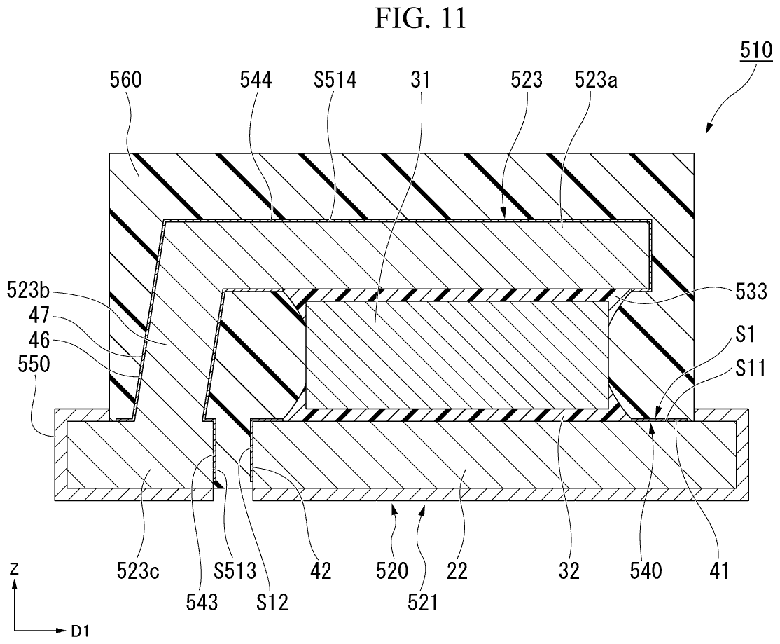

FIG. 11 shows a cross-sectional view showing a semiconductor device 510 according to a fifth modification example of the embodiment. In the semiconductor device 510 according to the present modification example, the shape of a lead frame 521 is a shape different from the shape of the lead frame 21 according to the embodiment described above. In the following description, the same reference signs are applied to constituent elements having the same form as those in the embodiment described above, and description thereof will be omitted. The semiconductor device 510 according to the present modification example includes the semiconductor chip 31, a terminal 520, and a resin 560.

The terminal 520 electrically connects the semiconductor chip 31 and a power source (not shown) and a driven body (not shown) disposed outside the semiconductor device 510. In the present modification example, the terminal 520 includes the lead frame 521.

Both ends of the lead frame 521 in the first direction D1 protrude from the resin 560. In the present modification example, the lead frame 521 is constituted using copper. At least a portion on a surface region of the lead frame 521 is the first surface region S1. In the present modification example, the entire surface region of the lead frame 521 is the first surface region S1. The lead frame 521 has the first lead frame 22, and a second lead frame 523.

The second lead frame 523 has a fourth part 523a, a fifth part 523b, and a sixth part 523c. The fourth part 523a has a plate shape spreading in a direction orthogonal to the vertical direction. The fourth part 523a is disposed above the semiconductor chip 31. The fourth part 523a is positioned inside the resin 560. The semiconductor chip 31 is fixed to a lower surface of the fourth part 523a with a joining material 533 therebetween. The fifth part 523b has a plate shape positioned on the downward side as it goes toward the other side in the first direction D1 (negative D1 side). An end portion of the fifth part 523b on one side in the first direction D1 (positive D1 side) leads to an end portion of the fourth part 523a on the other side in the first direction D1. The fifth part 523b is positioned inside the resin 560. The sixth part 523c has a plate shape spreading in a direction orthogonal to the vertical direction. An end portion of the sixth part 523c on one side in the first direction D1 leads to a lower end of the fifth part 523b. A portion of the sixth part 523c is positioned inside the resin 560. An end portion of the sixth part 523c on the other side in the first direction D1 is positioned on the outward side of the resin 560. The second lead frame 523 has a third surface region part S513 and a fourth surface region part S514.

The third surface region part S513 includes a part on the other side in the first direction D1 (negative D1 side) from the joining material 533 on the lower surface of the fourth part 523a, a surface facing one side of the fifth part 523b in the first direction D1 (positive D1 side), and a surface facing one side of the sixth part 523c in the first direction D1. The third surface region part S513 is the first surface region S1. The third surface region part S513 is covered by the resin 560.

The fourth surface region part S514 includes a part on one side in the first direction D1 (positive D1 side) from the joining material 533 on the lower surface of the fourth part 523a, a surface facing one side of the fourth part 523a in the first direction D1, the upper surface of the fourth part 523a, a surface facing the other side of the fifth part 523b in the first direction D1, and a part on one side in the first direction D1 on the upper surface of the sixth part 523c. The fourth surface region part S514 is the first surface region S1. The fourth surface region part S514 is covered by the resin 560. A plated layer 550 is formed in parts on the surface of the lead frame 521 positioned outside the resin 560. Other constitutions and the like of the terminal 520 according to the present modification example are similar to other constitutions and the like of the terminal 20 according to the embodiment described above.

In the present modification example, a functional film 540 is formed in at least a portion of the part on the first surface region S1 of the terminal 520 covered by the resin 560. In the present modification example, the functional film 540 is formed in each of the first surface region part S11, the second surface region part S12, the third surface region part S513, and the fourth surface region part S514. The outer surface of the functional film 540 comes into contact with the resin 560. In the present modification example, the functional film 540 includes the first functional film portion 41, the second functional film portion 42, a third functional film portion 543, and a fourth functional film portion 544.

The first functional film portion 41 is formed in the first surface region part S11. The second functional film portion 42 is formed in the second surface region part S12. The third functional film portion 543 is formed in the third surface region part S513. The fourth functional film portion 544 is formed in the fourth surface region part S514. Similar to the functional film 40 according to the embodiment described above, the functional film 540 comprises the copper oxide film 46 and the organic film 47. Other constitutions and the like of the functional film 540 according to the present modification example are similar to other constitutions and the like of the functional film 40 according to the embodiment described above.

The resin 560 covers a portion of the terminal 520, and the semiconductor chip 31. The resin 560 seals the first surface region part S11, the second surface region part S12, the third surface region part S513, the fourth surface region part S514, and the surface of the semiconductor chip 31 from the outside air. A portion of the resin 560 is firmly bonded to the functional film 540 formed on the first surface region S1 of the terminal 520. More specifically, a portion of the resin 560 is firmly bonded to the organic film 47. In the present modification example, the resin 560 is bonded to the organic film 47 by covalent bonds via carbon atoms.

According to the present modification example, the functional film 540 comprising the organic film 47 containing oxygen atoms is formed in at least a portion of the part on the first surface region S1 of the terminal 520 covered by the resin 560, and the organic film 47 is bonded to the resin 560. Accordingly, similar to the embodiment described above, since the organic film 47 and the resin 560 are bonded by covalent bonds via carbon atoms, a bonding force between the functional film 540 and the resin 560 can be enhanced. Therefore, since a bonding force between the terminal 520 and the resin 560 can be enhanced with the functional film 540 therebetween, a situation in which the resin 560 peels off from the terminal 520 can be curbed.

### Sixth Modification Example

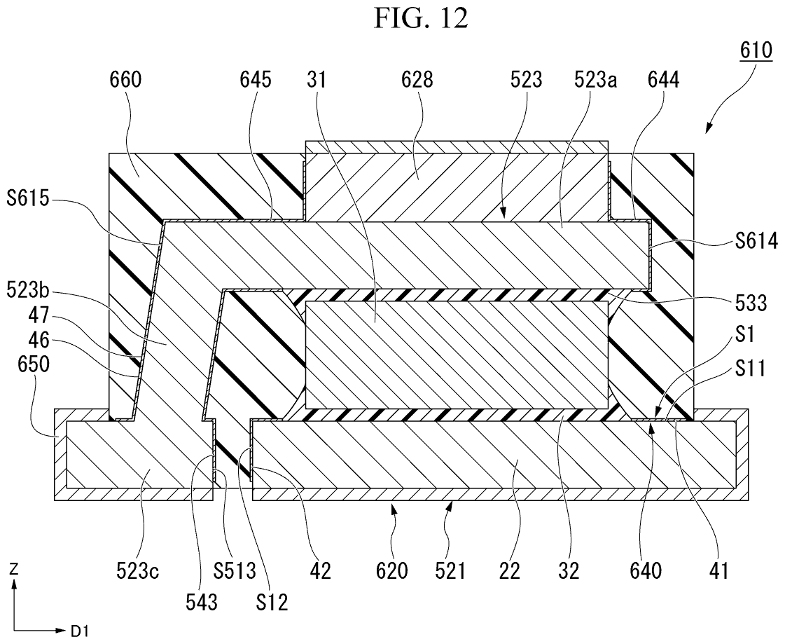

FIG. 12 shows a cross-sectional view showing a semiconductor device 610 according to a sixth modification example of the embodiment. The semiconductor device 610 according to the present modification example has a heat dissipation portion 628. In the following description, the same reference signs are applied to constituent elements having the same form as those in the fifth modification example of the embodiment described above, and description thereof will be omitted. The semiconductor device 610 according to the present modification example includes the semiconductor chip 31, a terminal 620, and a resin 660. The terminal 620 includes the lead frame 521 and the heat dissipation portion 628.

The heat dissipation portion 628 has a plate shape spreading in a direction orthogonal to the vertical direction. In the present modification example, the heat dissipation portion 628 is constituted using copper. For this reason, a surface of the heat dissipation portion 628 is the first surface region S1. The heat dissipation portion 628 is fixed to the upper surface of the fourth part 523a. The upper surface of the heat dissipation portion 628 is positioned above the resin 660. Accordingly, during operation of the semiconductor device 610, heat generated in the semiconductor chip 31 dissipates to the outside of the semiconductor device 610 via the first lead frame 22 and also dissipates to the outside of the semiconductor device 610 via the second lead frame 523 and the heat dissipation portion 628. For this reason, compared to a constitution in which the semiconductor device 610 does not have the heat dissipation portion 628, a rise in temperature of the semiconductor chip 31 during operation of the semiconductor device 610 can be curbed. Therefore, since stability of operation of the semiconductor device 610 can be enhanced, reliability of the semiconductor device 610 can be more favorably enhanced.

In the present modification example, the terminal 620 has the first surface region part S11, the second surface region part S12, the third surface region part S513, a fourth surface region part S614, and a fifth surface region part S615.

The fourth surface region part S614 includes a part on one side in the first direction D1 (positive D1 side) from the joining material 533 on the lower surface of the fourth part 523a, a surface facing one side of the fourth part 523a in the first direction D1, a part on one side in the first direction D1 from the heat dissipation portion 628 on the upper surface of the fourth part 523a, and a surface facing one side of the heat dissipation portion 628 in the first direction D1. The fourth surface region part S614 is the first surface region S1. The fourth surface region part S614 is covered by the resin 660.

The fifth surface region part S615 includes a surface facing the other side of the heat dissipation portion 628 in the first direction D1 (negative D1 side), a part on the other side in the first direction D1 from the heat dissipation portion 628 on the upper surface of the fourth part 523a, a surface facing the other side of the fifth part 523b in the first direction D1, and a part on one side in the first direction D1 (positive D1 side) on the upper surface of the sixth part 523c. The fifth surface region part S615 is the first surface region S1. The fifth surface region part S615 is covered by the resin 660. A plated layer 650 is formed in parts on the surface of the lead frame 521 and the surface of the heat dissipation portion 628 positioned outside the resin 660. Other constitutions and the like of the terminal 620 according to the present modification example are similar to other constitutions and the like of the terminal 520 according to the fifth modification example of the embodiment described above.

In the present modification example, a functional film 640 is formed in at least a portion of the part on the first surface region S1 of the terminal 620 covered by the resin 660. In the present modification example, the functional film 640 is formed in each of the first surface region part S11, the second surface region part S12, the third surface region part S513, the fourth surface region part S614, and the fifth surface region part S615. The outer surface of the functional film 640 comes into contact with the resin 660. In the present modification example, the functional film 640 includes the first functional film portion 41, the second functional film portion 42, the third functional film portion 543, a fourth functional film portion 644, and a fifth functional film portion 645. The fourth functional film portion 644 is formed in the fourth surface region part S614. The fifth functional film portion 645 is formed in the fifth surface region part S615. Similar to the functional film 40 according to the embodiment described above, the functional film 640 comprises the copper oxide film 46 and the organic film 47. Other constitutions and the like of the functional film 640 according to the present modification example are similar to other constitutions and the like of the functional film 540 according to the fifth modification example of the embodiment described above.

The resin 660 covers a portion of the terminal 620, and the semiconductor chip 31. The resin 660 seals the first surface region part S11, the second surface region part S12, the third surface region part S513, the fourth surface region part S614, the fifth surface region part S615, and the surface of the semiconductor chip 31 from the outside air. A portion of the resin 660 is firmly bonded to the functional film 640 formed on the first surface region S1 of the terminal 620. More specifically, a portion of the resin 660 is firmly bonded to the organic film 47. In the present modification example, the resin 660 is bonded to the organic film 47 by covalent bonds via carbon atoms.

According to the present modification example, the functional film 640 comprising the organic film 47 containing oxygen atoms is formed in at least a portion of the part on the first surface region S1 of the terminal 620 covered by the resin 660, and the organic film 47 is bonded to the resin 660. Accordingly, similar to the embodiment described above, since the organic film 47 and the resin 660 are bonded by covalent bonds via carbon atoms, a bonding force between the functional film 640 and the resin 660 can be enhanced. Therefore, since a bonding force between the terminal 620 and the resin 660 can be enhanced with the functional film 640 therebetween, a situation in which the resin 660 peels off from the terminal 620 can be curbed.

According to semiconductor device of at least one embodiment described above, it is possible to provide a semiconductor device capable of curbing a situation in which a resin peels off from a terminal by forming a functional film comprising an organic film containing oxygen atoms in at least a portion of a part on a first surface region covered by the resin.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a semiconductor chip;
a terminal which is connected to the semiconductor chip and which comprises a first surface region containing copper, and
a functional film formed on at least a portion of a surface of the first surface region; and
a resin which covers a portion of the terminal and the semiconductor chip,
wherein the functional film comprises an organic film containing oxygen atoms, and
the organic film is bonded to the resin.

2. The semiconductor device according to claim 1,
wherein the functional film comprises a copper oxide film constituted using copper oxide between the first surface region and the organic film, and
the copper oxide film is firmly bonded to the first surface region.

3. The semiconductor device according to claim 2,
wherein a thickness of the copper oxide film is 1 nm to 15 nm.

4. The semiconductor device according to claim 2,
wherein a thickness of the organic film is 10 nm to 200 nm.

5. The semiconductor device according to claim 4,
wherein the thickness of the organic film is 10 nm to 60 nm.

6. The semiconductor device according to claim 1,
wherein at least a portion of the terminal is constituted using one or more any of copper, a copper-containing alloy, and a metal material other than copper having a copper-plated surface.

7. The semiconductor device according to claim 1,
wherein the terminal includes a lead frame, and a wire connecting the lead frame and the semiconductor chip to each other, and
at least a portion of each of a surface region of the lead frame and a surface region of the wire is the first surface region.

8. The semiconductor device according to claim 7,
wherein the terminal includes an electrode portion formed on the surface of the lead frame,
the electrode portion comprises a second surface region containing no copper, and
the functional film is not formed on a surface of the second surface region.

9. The semiconductor device according to claim 1,
wherein the terminal includes a lead frame, and a wire connecting the lead frame and the semiconductor chip to each other,
a surface region of the lead frame is the first surface region,
a surface region of the wire is a second surface region containing no copper, and
the functional film is not formed on the surface of the second surface region.

10. The semiconductor device according to claim 7,
wherein a plated layer is formed in a part positioned outside the resin on the surface of the lead frame, and
a distance between the functional film and the plated layer is 100 μm or longer.
